(19) United States
(12) Patent Application Publication
(10) Pub. No.: US 2013/0248850 A1
(43) Pub. Date: Sep. 26, 2013

(54) THIN FILM TRANSISTOR, DISPLAY APPARATUS HAVING THE SAME, AND METHOD OF MANUFACTURING THE SAME

(71) Applicants: Tae-Young CHOI, Seoul (KR); Bo Sung Kim, Seoul (KR); Byungju Lee, Gunpo-si (KR); Kangmoon Jo, Seoul (KR)

(72) Inventors: Tae-Young CHOI, Seoul (KR); Bo Sung Kim, Seoul (KR); Byungju Lee, Gunpo-si (KR); Kangmoon Jo, Seoul (KR)

(21) Appl. No.: 13/571,684

(22) Filed: Aug. 10, 2012

(30) Foreign Application Priority Data
Mar. 23, 2012 (KR) 10-2012-0030137

(51) Int. Cl. H01L 29/786; H01L 21/336; H01L 27/32

(52) U.S. Cl. 257/43; 257/59; 438/46; 257/E29.296; 257/E27.12; 257/E21.411

(57) ABSTRACT

A thin film transistor includes a source electrode, a drain electrode, a channel portion disposed between the source electrode and the drain electrode, and a gate electrode disposed on the channel portion and insulated from the channel portion. The source electrode, the drain electrode, and the channel portion are disposed on a same layer. A display apparatus includes a display device and the thin film transistor that applies a driving signal to the display device.

### CROSS-REFERENCE TO RELATED APPLICATION

This U.S. non-provisional patent application claims priority under 35 U.S.C. § 119 of Korean Patent Application No. 10-2012-0030137, filed on Mar. 23, 2012, the contents of which are herein incorporated by reference.

### TECHNICAL FIELD

Embodiments of the present disclosure relate to a thin film transistor, a display apparatus having the same, and a method of manufacturing the same, and more particularly to a top-gate type thin film transistor, a display apparatus having the top-gate type thin film transistor, and a method of manufacturing the top-gate type thin film transistor.

### DISCUSSION OF THE RELATED ART

In general, thin film transistors are used as switching devices in flat panel display devices, such as liquid crystal display devices, organic light emitting display devices, etc. The mobility or leakage current of thin film transistors depend on the material and state of a channel layer through which electric charge transporters (carriers) move.

When the channel layer of the thin film transistors is formed from amorphous silicon, the thin film transistors may be uniformly formed on a large substrate, but the mobility of the electric charges may be reduced.

Accordingly, there is a need for thin film transistors that may provide increased mobility of electric charges and drive speed, together with a simplified manufacturing process.

### SUMMARY

Embodiments of the present disclosure provide a thin film transistor that can increase a driving speed and simplify a manufacturing process, a display apparatus having the thin film transistor, and a method of manufacturing the thin film transistor.

An embodiment of the inventive concept provides a thin film transistor includes a source electrode, a drain electrode, a channel portion disposed between the source electrode and the drain electrode, and a gate electrode disposed on the channel portion and insulated from the channel portion. The source electrode, the drain electrode, and the channel portion are disposed on a same layer.

The source electrode includes a source electrode portion and a first doping portion that covers at least a portion of the source electrode portion, and the drain electrode includes a drain electrode portion and a second doping portion that covers at least a portion of the drain electrode portion. The first doping portion and the second doping portion are formed of a doped oxide semiconductor. The channel portion is disposed between the first doping portion and the second doping portion and formed of an oxide semiconductor doped with impurities.

The thin film transistor further includes a gate insulating layer disposed between the channel portion and the gate electrode, and the gate electrode, the gate insulating layer, and the channel portion have the same size and shape when viewed in a plan view.

An embodiment of the inventive concept provides a display apparatus includes a display device and a thin film transistor that applies a driving signal to the display device.

The display device includes a first electrode, a second electrode, and an image display layer disposed between the first electrode and the second electrode, and the thin film transistor is connected to the first electrode. The image display layer may be a liquid crystal layer, an organic light emitting layer, an electrophoretic layer, or an electrowetting layer.

An embodiment of the inventive concept provides a method of manufacturing a thin film transistor includes forming a source electrode portion and a drain electrode portion on a base substrate, forming an oxide semiconductor layer between the source electrode portion and the drain electrode portion, forming a gate electrode on the oxide semiconductor layer, and doping the oxide semiconductor layer with impurities using the gate electrode as a mask to form a first doping portion and a second doping portion, which are doped with the impurities, and a channel portion disposed between the first doping portion and the second doping portion.

The doping of the impurities includes forming a thin layer containing the impurities and annealing the base substrate on which the thin layer is formed. The doping of the impurities includes plasma-treating the base substrate using a gas of H2 or NH3.

The method of manufacturing a thin film transistor further includes forming a first electrode connected to a drain electrode of the thin film transistor, forming a second electrode facing the first electrode, and forming an image display layer between the first electrode and the second electrode.

According to the embodiments, the thin film transistor can be formed without damaging the channel portion of the thin film transistor.

In addition, no or little parasitic capacitance is generated between the gate electrode and the source electrode, and/or a parasitic capacitance between the gate electrode and the drain electrode, and thus the thin film transistor is stably operated.

Further, the display apparatus can provide stable, low-voltage displaying operation and a reduced manufacturing cost. Further, since the thin film transistor is uniformly formed on a large area at a relatively low temperature, the electronic device can be formed on a flexible substrate, such as a plastic substrate, which may be processed at a relatively low temperature.

### BRIEF DESCRIPTION OF THE DRAWINGS

The embodiments of the present invention will become readily apparent by reference to the following detailed description when considered in conjunction with the accompanying drawings wherein:

FIG. 1A is a cross-sectional view showing a thin film transistor according to an exemplary embodiment of the present invention;

FIGS. 1B to 1E are cross-sectional views showing a method of manufacturing a thin film transistor according to an exemplary embodiment of the present invention;

FIG. 2 is a circuit diagram showing a liquid crystal display device employing a thin film transistor according to an exemplary embodiment of the present invention;

FIG. 3A is a plan view showing a display apparatus according to an exemplary embodiment of the present invention;

FIG. 3B is a cross-sectional view taken along a line I-I′ shown in FIG. 3A;

FIGS. 4A, 5A, 6A, 7A, 8A, and 9A are plan views showing a method of manufacturing a display apparatus according to an exemplary embodiment of the present invention;

FIGS. 4B, 5B, 6B, 7B, 8B, and 9B are cross-sectional views taken along a line I-I′ shown in FIGS. 4A, 5A, 6A, 7A, 8A, and 9A, respectively;

FIG. 10 is a circuit diagram showing an organic light emitting display device employing a thin film transistor according to an exemplary embodiment of the present invention;

FIG. 11A is a plan view showing a display apparatus according to an exemplary embodiment of the present invention;

FIG. 11B is a cross-sectional view taken along a line II-II′ shown in FIG. 11A;

FIGS. 12A, 13A, 14A, 15A, 16A, and 17A are plan views showing a method of manufacturing a display apparatus according to an exemplary embodiment of the present invention; and

FIGS. 12B, 13B, 14B, 15B, 16B, and 17B are cross-sectional views taken along a line II-II′ shown in FIGS. 12A, 13A, 14A, 15A, 16A, and 17A, respectively.

### DETAILED DESCRIPTION

It will be understood that when an element or layer is referred to as being “on”, “connected to” or “coupled to” another element or layer, it can be directly on, connected or coupled to the other element or layer or intervening elements or layers may be present. As used herein, the singular forms, “a”, “an” and “the” are intended to include the plural forms as well, unless the context clearly indicates otherwise.

As will be appreciated by one skilled in the art, embodiments of the present invention may be embodied as a system, method, computer program product, or a computer program product embodied in one or more computer readable medium(s) having computer readable program code embodied thereon. The computer readable program code may be provided to a processor of a general purpose computer, special purpose computer, or other programmable data processing apparatus. The computer readable medium may be a computer readable signal medium or a computer readable storage medium. The computer readable storage medium may be any tangible medium that can contain, or store a program for use by or in connection with an instruction execution system, apparatus, or device.

Hereinafter, the embodiments of the present invention will be described in detail with reference to the accompanying drawings.

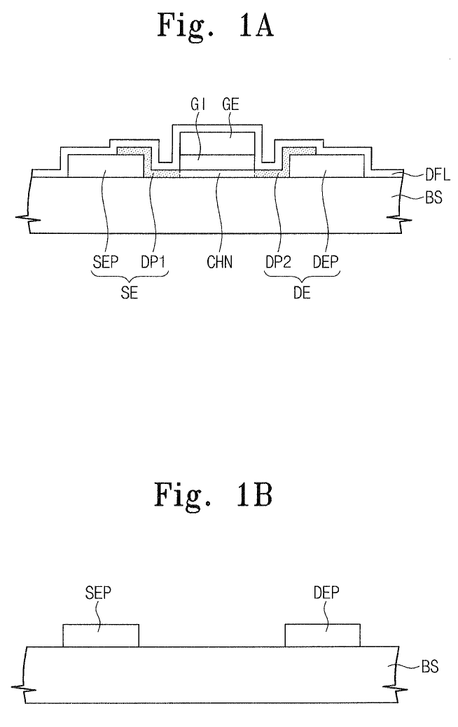

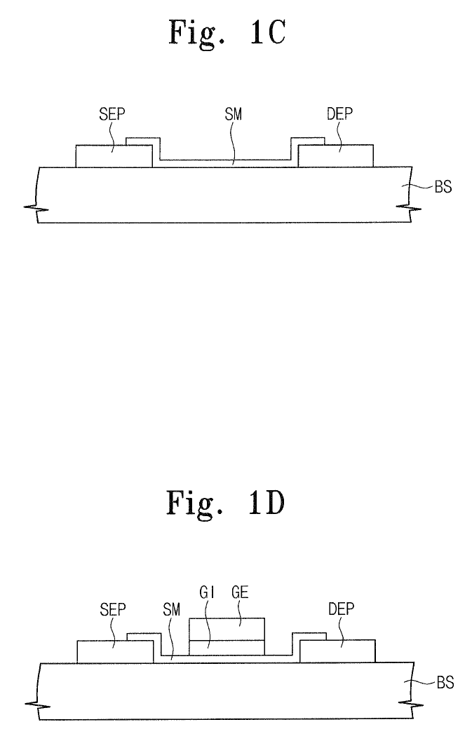

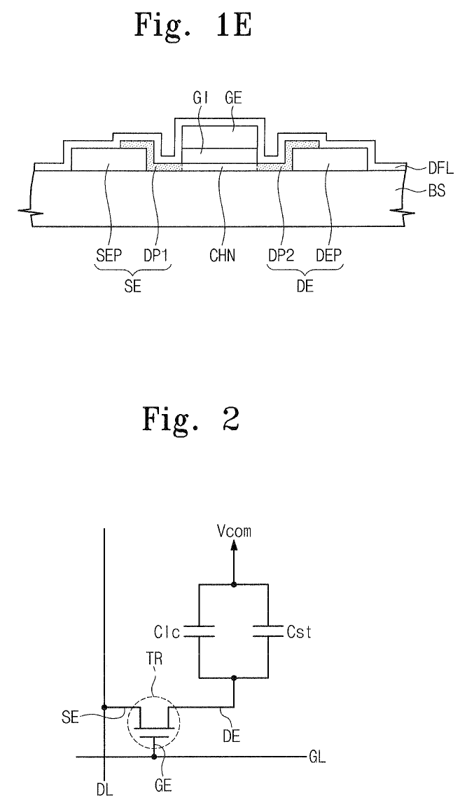

FIG. 1A is a cross-sectional view showing a thin film transistor according to an exemplary embodiment of the present invention, and FIGS. 1B to 1E are cross-sectional views showing a method of manufacturing a thin film transistor according to an exemplary embodiment of the present invention.

Referring to FIG. 1A, the thin film transistor includes a source electrode SE, a drain electrode DE, a channel portion CHN, and a gate electrode GE.

The source electrode SE and the drain electrode DE are disposed on a base substrate BS and are spaced apart from each other. According to an embodiment, the base substrate BS includes, but not limited to, a silicon substrate, a glass substrate, or a plastic substrate. According to an embodiment, the base substrate BS is transparent or non-transparent.

The source electrode SE includes a source electrode portion SEP and a first doping portion DP1 that covers at least a portion of the source portion SEP.

The source electrode portion SEP includes an upper surface substantially in parallel with an upper surface of the base substrate BS and a side surface that connects the upper surface of the source electrode portion SEP with the base substrate BS. The source electrode portion SEP includes a conductive material, such as a metal and/or a metal oxide. The source electrode portion SEP includes a single metal or a single metal oxide, two or more metals and/or metal oxides, or alloys of two or more metals. The source electrode portion SEP has a single-layer structure or a multi-layer structure. For instance, according to an embodiment, the source electrode portion SEP has a double-layer structure of titanium and copper. According to an embodiment, the source electrode portion SEP includes a copper layer and a metal oxide layer disposed on an upper or lower portion of the copper layer. According to an embodiment, the metal oxide layer includes indium tin oxide, indium zinc oxide, gallium zinc oxide, and zinc aluminum oxide. The source electrode portion SEP has a thickness of about 400 nm or more.

The first doping portion DP1 covers at least a portion of the upper surface of the source electrode portion SEP, the side surface of the source electrode portion SEP, and the upper surface of the base substrate BS, and directly contacts the source electrode portion SEP. The first doping portion DP1 is formed of an oxide semiconductor highly doped with impurities and has conductivity. The oxide semiconductor includes at least one of indium (In), gallium (Ga), zinc (Zn), or tin (Sn). The first doping portion DP1 includes the oxide semiconductor, such as zinc oxide, tin oxide, indium oxide, In-Zn oxide, In—Sn oxide, In—Ga—Zn oxide, In—Zn—Sn oxide, or In—Ga—Zn—Sn oxide, and is doped with impurities, such as aluminum.

The drain electrode DE includes a drain electrode portion DEP and a second doping portion. DP2 that covers at least a portion of the drain electrode DE.

The drain electrode portion DEP includes an upper surface substantially in parallel with an upper surface of the base substrate BS and a side surface that connects the upper surface of the drain electrode portion DEP with the base substrate BS. The drain electrode portion DEP includes a conductive material, such as a metal and/or a metal oxide. The drain electrode portion DEP includes a single metal or a single metal oxide, two or more metals and/or metal oxides, or alloys of two or more metals. According to an embodiment, the drain electrode portion DEP has a single-layer structure or a multi-layer structure. For instance, according to an embodiment, the drain electrode portion DEP has a double-layer structure of titanium and copper. According to an embodiment, the drain electrode portion DEP includes a copper layer and a metal oxide layer disposed on an upper or lower portion of the copper layer. According to an embodiment, the metal oxide layer includes indium tin oxide, indium zinc oxide, gallium zinc oxide, and zinc aluminum oxide. The source electrode portion SEP has a thickness of about 400 nm or more.

The second doping portion DP2 covers at least a portion of the upper surface of the drain electrode portion DEP, the side surface of the drain electrode portion DEP, and the upper surface of the base substrate BS and directly contacts the drain electrode portion DEP. The second doping portion DP2 is formed of an oxide semiconductor highly doped with impurities and has conductivity. The oxide semiconductor includes at least one of indium (In), gallium (Ga), zinc (Zn), or tin (Sn). The second doping portion DP2 includes the oxide semiconductor, such as zinc oxide, tin oxide, indium oxide, In—Zn oxide, In—Sn oxide, In—Ga—Zn oxide, In—Zn—Sn oxide, or In—Ga—Zn—Sn oxide, and is doped with impurities, such as aluminum.

The channel portion CHN is provided between the source electrode SE and the drain electrode DE, particularly between the first doping portion DP1 and the second doping portion DP2. The channel portion CHN is disposed on the same or substantially the same layer as the source electrode SE and the drain electrode DE. In other words, the channel portion CHN, the source electrode SE, and the drain electrode DE are disposed on the upper surface of the base substrate BS or on a plane parallel or substantially parallel with the upper surface of the base substrate BS. For instance, according to an embodiment, as show in FIG. 1A, the channel portion CHN, the source electrode SE, and the drain electrode DE directly contact the upper surface of the base substrate BS, and no other elements are disposed between the base substrate BS and the channel portion CHN, the source electrode SE, and the drain electrode DE. According to an embodiment, an additional layer, such as a diffusion preventing layer used to prevent the diffusion of the impurities, is disposed between the base substrate BS and the channel portion CHN, the source electrode SE, and the drain electrode DE. In this case, the channel portion CHN, the source electrode SE, and the drain electrode DE are disposed on the additional layer.

The channel portion CHN is formed of an oxide semiconductor, which is doped with no impurities or doped with impurities having a lower concentration than a concentration of the first doping portion DP1 or the second doping portion DP2. According to an embodiment, the oxide semiconductor includes at least one of indium (In), gallium (Ga), zinc (Zn), or tin (Sn). The channel portion CHN includes the oxide semiconductor, such as zinc oxide, tin oxide, indium oxide, In—Zn oxide, In—Sn oxide, In—Ga—Zn oxide, In—Zn—Sn oxide, or In—Ga—Zn—Sn oxide and is doped with impurities, such as aluminum. Each of the first doping portion DP1, the second doping portion DP2, and the channel portion CHN has a thickness of about 150 nm or less, which is smaller than thicknesses of the source electrode portion SEP and the drain electrode portion DEP.

A gate insulating layer GI is disposed on the channel portion CHN to insulate the gate electrode GE and the channel CHN from each other.

The gate electrode GE is disposed on the gate insulating layer GI. The gate electrode GE and the source electrode portion SEP are spaced apart from each other, and at least a portion of the first doping portion DP1 is positioned between the gate electrode GE and the source electrode portion SEP. The gate electrode GE and the drain electrode portion DEP are spaced apart from each other, and at least a portion of the second doping portion DP2 is positioned between the gate electrode GE and the drain electrode portion DEP.

The gate electrode GE includes a conductive material, such as a metal and/or a metal oxide. According to an embodiment, the gate electrode GE includes a single metal or a single metal oxide, two or more metals and/or metal oxides, or alloys of two or more metals.

According to an embodiment, the gate electrode GE has a single-layer structure or a multi-layer structure. According to an embodiment, the gate electrode GE includes a copper layer and a metal oxide layer disposed on an upper or lower portion of the copper layer. According to an embodiment, the metal oxide layer includes indium tin oxide, indium zinc oxide, gallium zinc oxide, and zinc aluminum oxide.

The gate electrode GE, the gate insulating layer GI, and the channel portion CHN have the same or substantially the same size and shape when viewed in a plan view.

Referring to FIG. 1B, the source electrode portion SEP and the drain electrode portion DEP are formed on the base substrate BS.

The source electrode portion SEP and the drain electrode portion DEP are formed of a conductive material, such as a metal material. For instance, according to an embodiment, the source electrode portion SEP and the drain electrode portion DEP are formed by forming a metal layer on the base substrate BS and patterning the metal layer using a photolithography process. Each of the source electrode portion SEP and the drain electrode portion DEP has a single-layer structure of a single metal layer or an alloy, but it should not be limited thereto or thereby. According to an embodiment, each of the source electrode portion SEP and the drain electrode portion DEP has a multi-layer structure of two or more metals and/or alloys thereof.

Referring to FIG. 1C, an oxide semiconductor layer SM is formed between the source electrode portion SEP and the drain electrode portion DEP. The oxide semiconductor layer SM overlaps and covers at least a portion of the source electrode portion SEP and the drain electrode portion DEP. The oxide semiconductor layer SM is formed of an oxide material including at least one of indium (In), gallium (Ga), zinc (Zn), or tin (Sn). The oxide semiconductor layer SM is formed by forming the oxide material layer between the source electrode portion SEP and the drain electrode portion DEP and patterning the oxide material layer using a photolithography process.

Referring to FIG. 1D, the gate insulating layer GI and the gate electrode GE are formed on the oxide semiconductor layer SM. The gate insulating layer GI and the gate electrode GE are formed by sequentially forming an insulating material, such as silicon nitride or silicon oxide, and a conductive material, such as metal, on the base substrate BS and patterning the insulating material and the conductive material using a photolithography process. The gate insulating layer GI and the gate electrode GE are disposed between the source electrode portion SEP and the drain electrode portion DEP and spaced apart from the source electrode portion SEP and the drain electrode portion DEP.

Referring to FIG. 1E, the first doping portion DP1 and the second doping portion DP2, which are doped with a high concentration of impurities and the undoped channel portion CHN are formed.

The first doping portion DPI, the second doping portion DP2, and the channel portion CHN are formed by forming a diffusion layer DFL on the base substrate BS on which the source electrode portion SEP, the drain electrode portion DEP, and the oxide semiconductor layer SM are formed and by annealing the diffusion layer DFL so that the impurities in the diffusion layer DFL are diffused into the oxide semiconductor layer SM. For instance, the diffusion layer DFL is formed on the base substrate BS using a sputtering process. The sputtering process utilizes a target (e.g., an aluminum target or aluminum oxide target) including impurities, such as aluminum. Then, the impurities in the diffusion layer DFL are diffused into the oxide semiconductor layer SM by the annealing process. As a result, the portions of the oxide semiconductor layer SM, which directly contact the diffusion layer DFL, are doped with the high concentration of impurities, so the doped portions of the oxide semiconductor layer SM function as the first doping portion DP1 and the second doping portion DP2, respectively. However, the portion of the oxide semiconductor layer SM, which is covered with the gate insulating layer GI and the gate electrode GE, is not doped with the impurities due to the gate insulating layer GI and the gate electrode GE, and thus serves as the channel portion CHN having physical properties of the oxide semiconductor. In other words, when the oxide semiconductor layer SM is doped with the impurities, the gate electrode GE (and the gate insulating layer GI) is used as a mask, and the portion of the oxide semiconductor layer SM, which is covered by the mask, becomes the channel portion CHN. Accordingly, the gate electrode GE, the gate insulating layer GI, and the channel portion CHN have the same size and the same shape when viewed in a plan view and are overlapped with each other.

Alternatively, the first doping portion DP1, the second doping portion DP2, and the channel portion CHN are formed by using a plasma process. When the first doping portion DP1, the second doping portion DP2, and the channel portion CHN are formed using the plasma process, the diffusion layer DFL may be omitted. The plasma process is performed by plasma-treating the base substrate BS, on which the first doping portion DP1, the second doping portion DP2, and the channel portion CHN are formed, using impurities including H_{2 or NH}₃. The portions of the oxide semiconductor layer SM, which are exposed to the exterior and not covered by the gate electrode GE and the gate insulating layer GI, are doped with hydrogen through the plasma-treating process, and thus the first doping portion DP1 and the second doping portion DP2 are formed. The portion of the oxide semiconductor layer SM, which is covered with the gate insulating layer GI and the gate electrode GE, is not plasma-treated, so that the portion of the oxide semiconductor layer SM, which is covered by the gate insulating layer GI and the gate electrode GE, is not doped with the impurities. For example, the gate electrode GE (and the gate insulting layer GI) is used as a mask when the oxide semiconductor layer SM is doped with the impurities, and the portion of the oxide semiconductor layer SM, which is covered by the mask, is formed as the channel portion CHN.

In the case that a source electrode and a drain electrode which each include a metal layer are formed by patterning the metal layer after a channel portion is formed, the channel portion may be damaged by the patterning.

In the thin film transistor according to an exemplary embodiment, however, the channel portion CHN is formed after the source electrode portion SEP and the drain electrode portion DEP are formed. Accordingly, the channel portion CHN may be prevented from being damaged. A deterioration of an off-current of the thin film transistor, which is caused by residues generated after the source electrode portion and the drain electrode portion are formed, may be prevented.

The gate electrode is not overlapped with the source electrode portion (or source electrode) or the drain electrode portion (or drain electrode). Since the first doping portion and the second doping portion are self-aligned in accordance with the position of the gate electrode, the gate electrode is further prevented from overlapping the source and drain electrodes. Thus, no or little parasitic capacitance is generated between the gate electrode and the source electrode and the gate electrode and the drain electrode, and thus the thin film transistor is stably operated.

Since the thin film transistor includes the channel portion formed of the oxide semiconductor, the thin film transistor has a low off-current. Therefore, the thin film transistor is operated at a low voltage. The oxide semiconductor is formed into a film on a large area at a low temperature when compared with the conventional semiconductors, such as silicon, and the film-forming may be performed under a non-vacuum state. Accordingly, the thin film transistor is uniformly formed on the large area with a uniform quality, thereby resulting in a simplified manufacturing process and reduced manufacturing cost.

The thin film transistor according to an exemplary embodiment may have applications for various electronic devices, for example, display apparatuses. According to an exemplary embodiment, a display apparatus includes a display device and thin film transistors for applying driving signals to the display device.

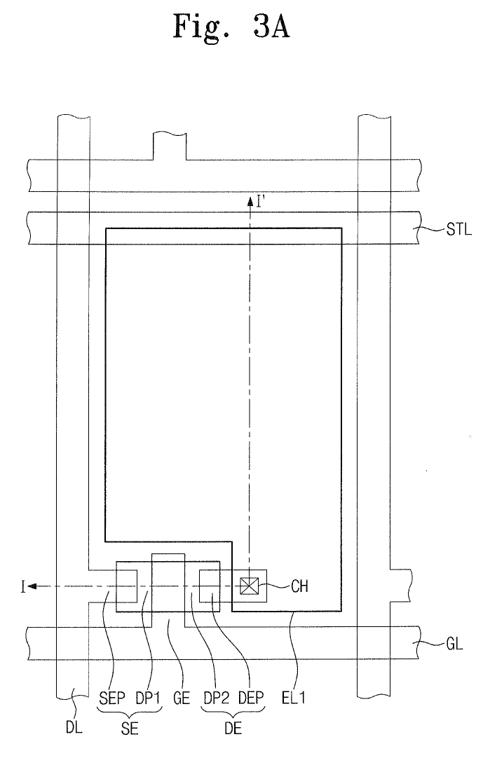

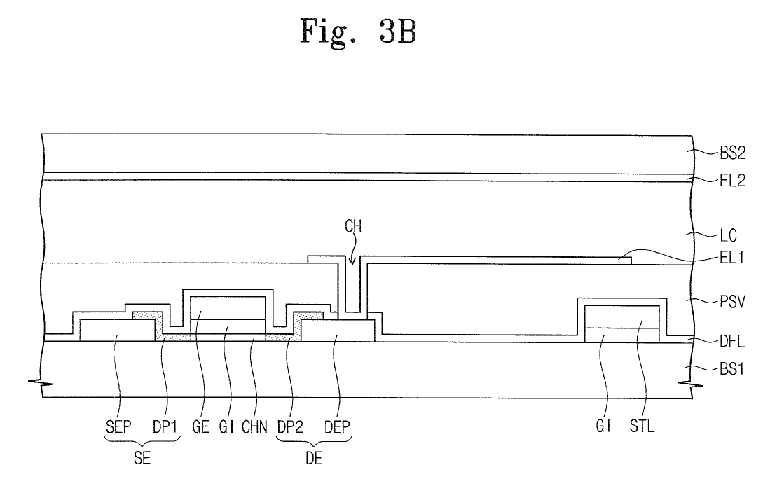

FIG. 2 is a circuit diagram showing a liquid crystal display device employing a thin film transistor according to an exemplary embodiment of the present invention. FIG. 3A is a plan view showing a display apparatus according to an exemplary embodiment of the present invention, and FIG. 3B is a cross-sectional view taken along a line I-I′ shown in FIG. 3A. The display apparatus according to an exemplary embodiment includes a plurality of signal lines and a plurality of pixels arranged in a matrix form and respectively connected to the signal lines. FIGS. 2, 3A, and 3B respectively show a circuit diagram, a plan view, and a cross-sectional view corresponding to one pixel of the pixels. Although not shown in FIG. 2, the signal lines include a plurality of gate lines that transmit gate signals and a plurality of data lines that transmit data signals. One gate line GL of the gate lines and one data line DL of the data lines are shown in FIG. 2.

Referring to FIG. 2, the gate line GL is extended in a first direction, e.g., a row direction, and the data line DL is extended in a second direction, e.g., a column direction, crossing the first direction.

The pixel includes a thin film transistor TR, a liquid crystal capacitor Clc, and a storage capacitor Cst. The thin film transistor TR includes a gate electrode GE connected to the gate line GL, a source electrode SE connected to the data line DL, and a drain electrode DE connected to the liquid crystal capacitor Clc and the storage capacitor Cst connected to a storage line STL.

When a turn-on voltage is applied to the gate electrode GE of the thin film transistor TR, the thin film transistor is turned on, and a data voltage is charged in the liquid crystal capacitor Clc and the storage capacitor Cst, which are connected to the drain electrode DE of the thin film transistor TR. The storage capacitor Cst is charged with the data voltage and maintains the data voltage after the thin film transistor TR is turned off.

Referring to FIGS. 3A and 3B, the display apparatus includes a first substrate including a first electrode EL1, a second substrate facing the first substrate and including a second electrode EL2, and a liquid crystal layer LC interposed between the first and second substrates.

The first substrate includes a thin film transistor substrate on which thin film transistors are formed and control the arrangement of liquid crystal molecules in the liquid crystal layer LC.

The first substrate includes a first base substrate BS1 and an electronic device disposed on the first base substrate BS 1.

The first base substrate BS1 is formed of a transparent insulating material, such as glass, silicon, crystal, or plastic, and has flexibility.

The electronic device includes the data line DL, the gate line GL, the storage line STL, the thin film transistor TR, and the first electrode EL1.

The data line DL is extended in the second direction, and the gate line GL is extended in the first direction crossing the second direction. The storage line STL is spaced apart from the gate line GL and extended in the first direction. The data line DL is insulated from the gate line GL and the storage line STL, and the gate insulating layer GI is disposed between the data line DL and the gate line GL and between the data line DL and the storage line STL.

The thin film transistor includes the gate electrode GE, the channel portion CHN, the source electrode SE, and the drain electrode DE.

The source electrode SE includes a source electrode portion SEP branched from the data line DL and the first doping portion DPI that covers at least a portion of the source electrode portion SEP and at least a portion of the upper surface of the first base substrate BS1. The drain electrode DE includes the drain electrode portion DEP spaced apart from the source electrode portion SEP and the second doping portion DP2 that covers at least a portion of the drain electrode portion DEP and at least a portion of the upper surface of the first base substrate BS1. A portion of each of the first and second doping portions DP1 and DP2 is disposed between the source electrode SEP and the drain electrode portion DEP.

The channel portion CHN is disposed between the source electrode SE and the drain electrode DE, particularly between the first doping portion DPI and the second doping portion DP2.

The gate insulating layer GI is disposed on the channel portion CHN to insulate the gate electrode GE and the channel portion CHN from each other.

The gate electrode GE is disposed on the gate insulating layer GI. The gate electrode GE is branched from the gate line GL. The gate electrode GE and the source electrode portion SEP are spaced apart from each other, and at least a portion of the first doping portion DPI is disposed between the gate electrode GE and the source electrode portion SEP. The gate electrode GE and the drain electrode portion DEP are spaced apart from each other, and at least a portion of the second doping portion DP2 is disposed between the gate electrode GE and the drain electrode portion DEP.

The gate electrode GE, the gate insulating layer GI, and the channel portion CHN have the same size and the same shape when viewed in a plan view.

The diffusion layer DFL and a passivation layer PSV are disposed on the thin film transistor TR. The diffusion layer DFL includes impurities and diffuses the impurities into the first doping portion DP1 and the second doping portion DP2. According to an embodiment, the diffusion layer DFL is omitted.

The first electrode EL1 is disposed on the passivation layer PSV. The diffusion layer DFL and the passivation layer PSV are penetrated by a contact hole CH to expose a portion of the drain electrode DE, and the first electrode EL1 is connected to the thin film transistor through the contact hole CH. The first electrode EL1 overlaps a portion of the storage line STL to form the storage capacitor Cst, and the passivation layer PSV is disposed between the first electrode EL1 and the portion of the storage line STL.

The second substrate includes a second base substrate BS2 facing the first base substrate BS1 and a second electrode EL2 disposed on the second base substrate BS2. The second electrode EL2 forms an electric field in cooperation with the first electrode EL1.

The second base substrate BS2 is formed of a transparent insulating material, such as glass, silicon, crystal, or plastic, and has flexibility.

The liquid crystal layer LC includes liquid crystal molecules having an anisotropic dielectric constant. When an electric field is generated between the first substrate and the second substrate, the liquid crystal molecules of the liquid crystal layer LC are oriented in a specific direction between the first substrate and the second substrate. Accordingly, the liquid crystal layer LC transmits or blocks light passing therethrough.

In the display apparatus having the above-mentioned structure, when a gate signal is applied to the gate electrode GE through the gate line GL, and a data signal is applied to the source electrode SE through the data line DL, a conductive channel is formed in the channel portion CHN. Thus, the thin film transistor is turned on, and an image signal is applied to the first electrode EL1, and thus an electric field is formed between the first electrode EL1 and a common electrode applied with a common voltage. The liquid crystal molecules of the liquid crystal layer LC are operated in accordance with the electric field, and the amount of light passing through the liquid crystal layer LC is controlled, thereby displaying images.

According to an exemplary embodiment, the display apparatus includes a separate light source. According to an embodiment, when the display apparatus is a transmissive or transflective type display apparatus, the light source includes, but not limited to, a backlight unit disposed adjacent to a side of the display apparatus. Alternatively, when the display apparatus is a reflective type display apparatus, the light source includes an external light source, such as sun. According to an embodiment, when the display apparatus is the transmissive or transflective type display apparatus, the display apparatus further includes a black matrix (not shown) disposed between the first base substrate and the channel portion to block light. The black matrix includes an organic material or an inorganic material, and according to an embodiment, an additional insulating layer is disposed between the black matrix and the channel portion. The black matrix blocks a leakage current generated when the light from the backlight unit directly contacts the channel portion.

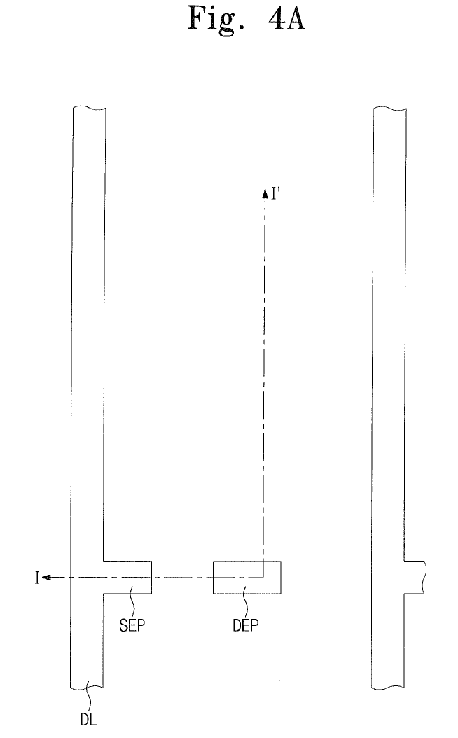

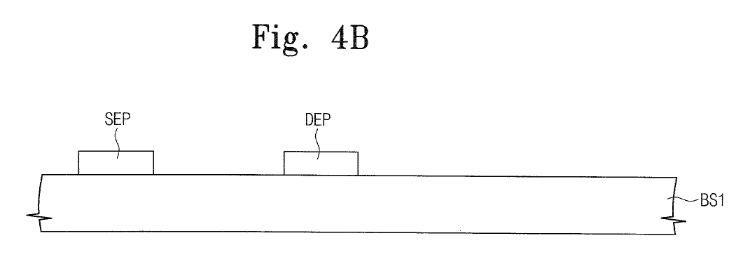

FIGS. 4A, 5A, 6A, 7A, 8A, and 9A are plan views showing a method of manufacturing a display apparatus according to an exemplary embodiment of the present invention, and FIGS. 4B, 5B, 6B, 7B, 8B, and 9B are cross-sectional views taken along a line I-I′ shown in FIGS. 4A, 5A, 6A, 7A, 8A, and 9A, respectively.

Referring to FIGS. 4A and 4B, a data line part is formed on the first base substrate BS1. The data line part includes the data line DL, the source electrode portion SEP, and the drain electrode portion DEP.

The data line part is formed of a conductive material, such as a metal. For instance, according to an embodiment, the data line part is formed by forming a metal layer over the first base substrate BS1 and patterning the metal layer using a photolithography process. According to an embodiment, the data line part has a single-layer structure of a single metal layer or an alloy of two or more metals, but it should not be limited thereto or thereby. According to an embodiment, the data line part has a multi-layer structure of two or more metals and/or alloys thereof. The data line DL and the source electrode portion SEP are integrally formed with each other as a single body.

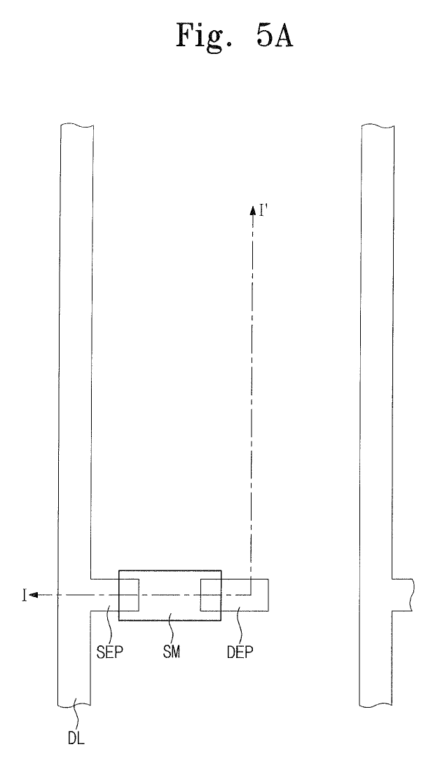

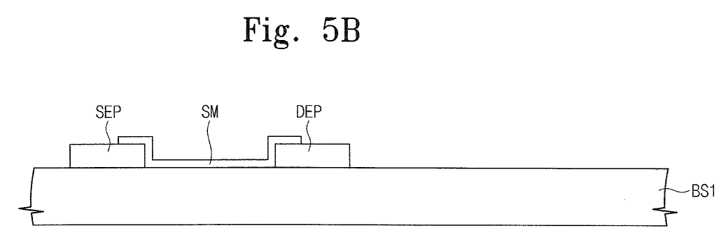

Referring to FIGS. 5A and 5B, an oxide semiconductor layer SM is formed between the source electrode portion SEP and the drain electrode portion DEP and on at least a portion of each of the source electrode portion SEP and the drain electrode portion DEP, so that the oxide semiconductor layer SM covers the portion of the source electrode portion SEP and the drain electrode portion DEP. According to an embodiment, the oxide semiconductor layer SM includes an oxide material having at least one of indium (In), gallium (Ga), zinc (Zn), or tin (Sn). The oxide semiconductor layer SM is formed by forming an oxide layer between the source electrode portion SEP and the drain electrode portion DEP and on portions of the source and drain electrode portions SEP and DEP and by patterning the oxide layer using a photolithography process.

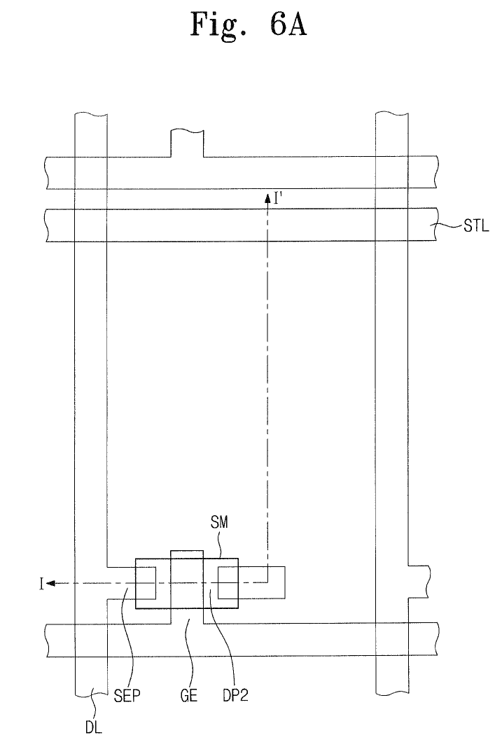

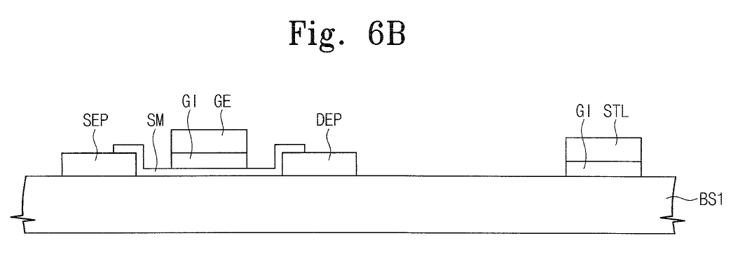

Referring to FIGS. 6A and 6B, the gate insulating layer GI and the gate line part are formed on the oxide semiconductor layer SM. The gate line part includes a gate line GL, a gate electrode GE, and a storage line STL. The gate insulating layer GI and the gate line part are formed by sequentially forming an insulating material, such as silicon nitride or silicon oxide, and a conductive material, such as metal, on the first base substrate BS1 and by patterning the insulating material and the conductive material using a photolithography process. The gate insulating layer GI and the gate electrode GE are disposed between the source electrode portion SEP and the drain electrode portion DEP and spaced apart from the source electrode portion SEP and the drain electrode portion DEP.

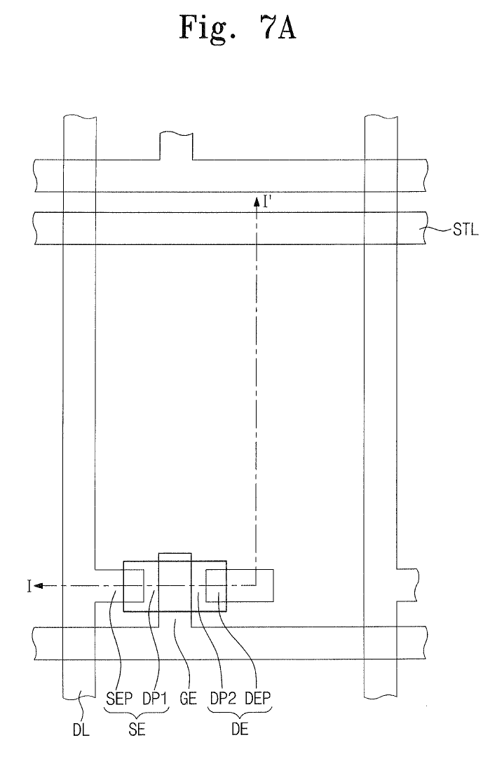

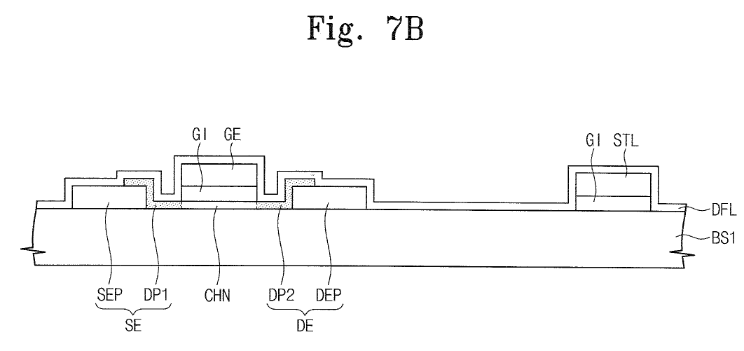

Referring to FIGS. 7A and 7B, the first doping portion DP1 and the second doping portion DP2, which are doped with the high concentration of impurities, and the channel portion CHN, which is not doped with the impurities, are formed.

The first doping portion DP 1, the second doping portion DP2, and the channel portion CHN are formed by forming the diffusion layer DFL on the first base substrate BS1 on which the source electrode portion SEP, the drain electrode portion DEP, and the oxide semiconductor layer SM are formed and by annealing the diffusion layer DFL so that the impurities in the diffusion layer DFL are diffused into the oxide semiconductor layer SM. Alternatively, the first doping portion DP1, the second doping portion DP2, and the channel portion CHN are formed using a plasma process. According to an embodiment, when the first doping portion DP1, the second doping portion DP2, and the channel portion CHN are formed by the plasma process, the diffusion layer DFL may be omitted. According to an embodiment, the plasma process is performed by plasma-treating the base substrate BS, on which the first doping portion DP1, the second doping portion DP2, and the channel portion CHN are formed, using impurities including, e.g., H₂ or NH₃. The portions of the oxide semiconductor layer SM, which are not covered by the gate electrode GE and the gate insulating layer GI, are doped with, e.g., hydrogen through the plasma-treating process, and thus the first doping portion DP1 and the second doping portion DP2 are formed. The portion of the oxide semiconductor layer SM, which is covered with the gate insulating layer GI and the gate electrode GE, is not plasma-treated, remains undoped with the impurities. For example, the gate electrode GE (and the gate insulting layer GI) is used as a mask when the oxide semiconductor layer SM is doped with the impurities, and the portion of the oxide semiconductor layer SM, which is covered by the mask, is formed as the channel portion CHN.

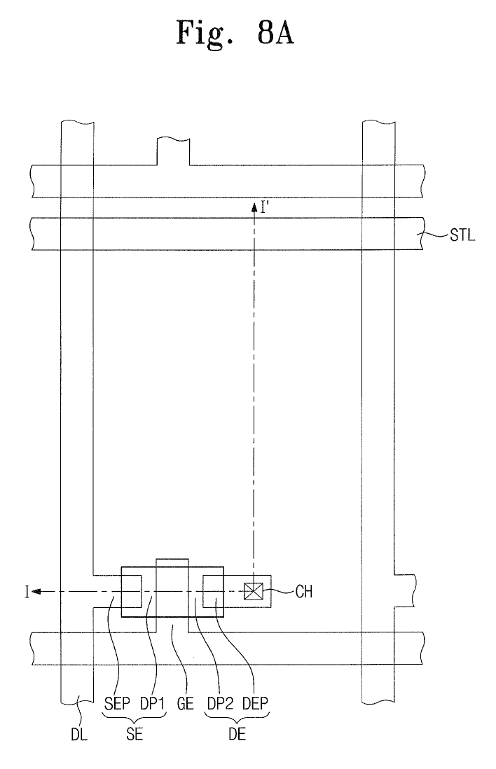

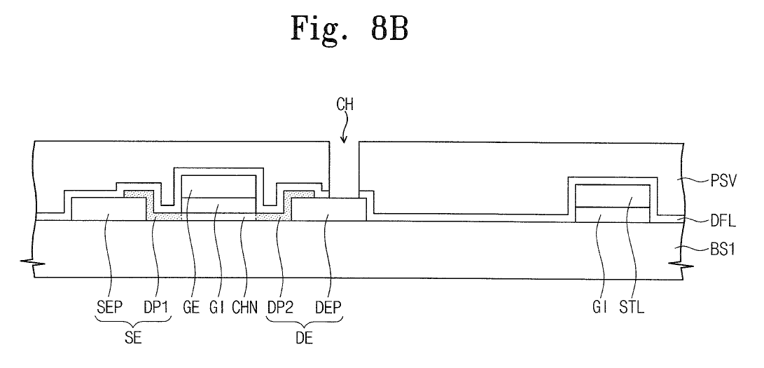

Referring to FIGS. 8A and 8B, the passivation layer PSV is formed on the first base substrate BS1, on which the first doping portion DP1, the second doping portion DP2, and the channel portion CHN are formed, using an insulating material. The contact hole CH is formed through the passivation layer PSV using, e.g., a photolithography process to expose the portion of the drain electrode DE.

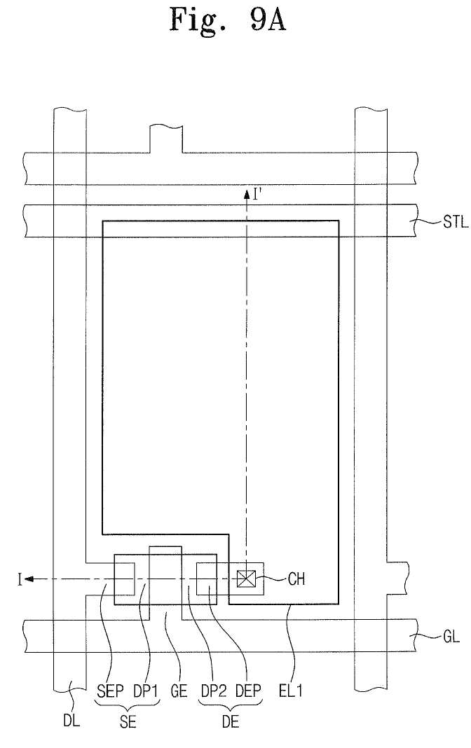

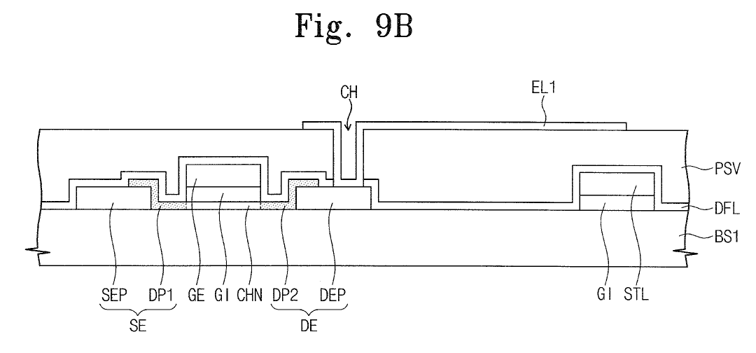

Referring to FIGS. 9A and 9B, the first electrode EL1. is formed on the first base substrate BS1 on which the passivation layer PSV is formed. The first electrode EL1 is formed by forming a conductive layer using a conductive material and patterning the conductive layer using a photolithography process. The first electrode EL1 is connected to the drain electrode DE through the contact hole CH. According to an embodiment, the first electrode EL1 is formed of a transparent material.

According to an embodiment, the first substrate is disposed to face the second substrate, and the liquid crystal layer LC is formed between the first substrate and the second substrate. The second substrate includes the second base substrate BS2 and the second electrode EL2 formed on the second base substrate BS2. According to an embodiment, the second electrode EL2 is formed of a transparent material.

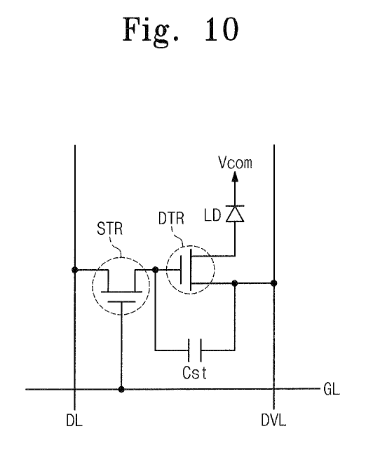

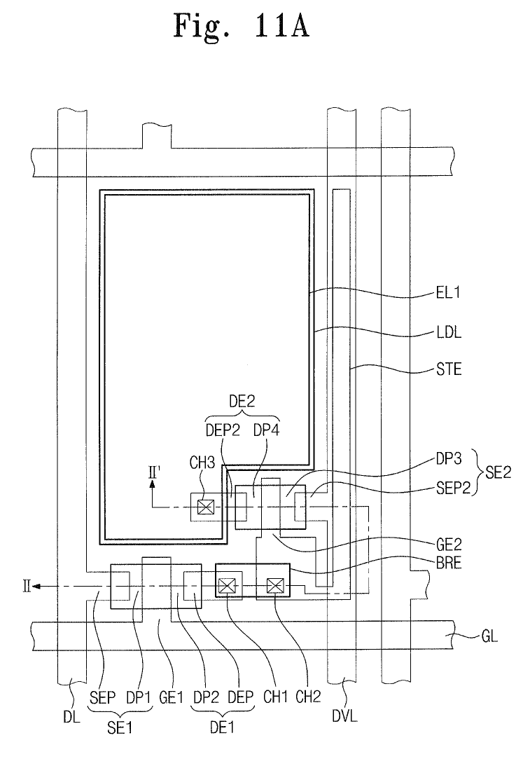

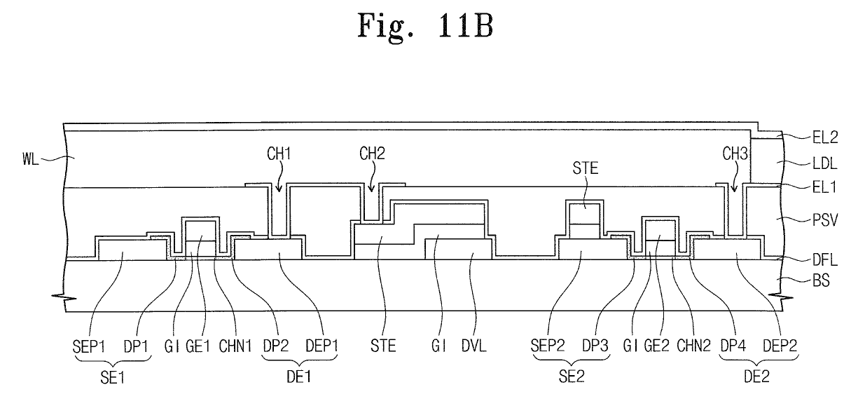

FIG. 10 is a circuit diagram showing an organic light emitting display device employing a thin film transistor according to an exemplary embodiment of the present invention. FIG. 11A is a plan view showing a display apparatus according to an exemplary embodiment of the present invention, and FIG. 11B is a cross-sectional view taken along a line II-II′ shown in FIG. 11A. The display apparatus according to an exemplary embodiment includes a plurality of signal lines and a plurality of pixels arranged in a matrix form and respectively connected to the signal lines. FIGS. 10, 11A, and 11B respectively show a circuit diagram, a plan view, and a cross-sectional view corresponding to one pixel of the pixels. Although not shown in FIG. 10, the signal lines include a plurality of gate lines that transmit gate signals and a plurality of data lines that transmit data signals. One gate line GL of the gate lines and one data line DL of the data lines are shown in FIG. 10.

Referring to FIGS. 10, 11A, and 11B, the signal lines includes the gate line GL, the data line DL, and a driving voltage line DVL through which a driving voltage is transmitted. The gate line GL is extended in a first direction, e.g., a row direction, and the data line DL and the driving voltage line DVL are extended in a second direction, e.g., a column direction.

The pixel includes a switching thin film transistor STR, a driving thin film transistor DTR, a storage capacitor Cst, and an organic light emitting diode LD.

The switching thin film transistor STR includes a first gate electrode GE1, a first source electrode SE1, and a first drain electrode DEL The first gate electrode GE1 is connected to the gate line GL, the first source electrode SE1 is connected to the data line DL, and the first drain electrode DE1 is connected to the driving thin film transistor DTR. The switching thin film transistor STR applies a data signal provided through the data line DL to the driving thin film transistor DTR in response to a gate signal provided through the gate line GL.

The driving thin film transistor DTR includes a second gate electrode GE2, a second source electrode SE2, and a second drain electrode DE2. The second gate electrode GE2 is connected to the first drain electrode DE1 of the switching thin film transistor STR, the second source electrode SE2 is connected to the driving voltage line DVL, and the second drain electrode DE2 is connected to the organic light emitting diode LD. The driving thin film transistor DTR applies an output voltage, which is varied depending on the applied voltage between the second gate electrode GE2 and the second drain electrode DE2, to the organic light emitting diode LD.

The storage capacitor Cst is connected between the second gate electrode GE2 and the second source electrode SE2 of the driving thin film transistor DTR. The storage capacitor Cst is charged with the data signal applied to the second gate electrode GE2 of the driving thin film transistor DTR and maintains the data signal after the switching thin film transistor STR is turned off

The organic light emitting diode LD includes a first electrode EU (e.g., anode) connected to the second drain electrode DE2 of the driving thin film transistor DTR and a second electrode EL2 (e.g., cathode) applied with a common voltage. The organic light emitting diode LD emits light having an intensity that varies depending on the output voltage of the driving thin film transistor DTR, thereby displaying an image.

Referring to FIGS. 10, 11A, and 11B, the display apparatus includes a base substrate BS, an electronic device disposed on the base substrate BS, and the organic light emitting layer LDL connected to the electronic device.

The electronic device includes the signal lines, the switching thin film transistor STR, the driving thin film transistor DTR, the first electrode EL1, and the second electrode EL2. The signal lines include the data line DL, the gate line GL, and the driving voltage line DVL.

The data line DL is disposed on the base substrate BS and extended in the second direction. The driving voltage line DVL is spaced apart from the data line DL and extended in the second direction. The gate line GL is extended in the first direction crossing the second direction. The data line DL and the driving voltage line DVL are insulated from the gate line GL, and a gate insulating layer GI is disposed between the data line DL and the gate line GL and between the driving voltage line DVL and the gate line GL.

The switching thin film transistor STR includes the first gate electrode GE1, a first channel portion CHN1, the first source electrode SE1, and the first drain electrode DE1.

The first source electrode SE1 includes a first source electrode portion SEP1 branched from the data line DL and the first doping portion DP1 that covers at least a portion of the first source electrode portion SEP1 and at least a portion of the upper surface of the base substrate BS. The first drain electrode DE1 includes the first drain electrode portion DEP1 spaced apart from the first source electrode portion SEP1 and the second doping portion DP2 that covers at least a portion of the first drain electrode portion DEP1 and at least a portion of the upper surface of the base substrate BS. A portion of each of the first and second doping portions DP1 and DP2 is disposed between the first source electrode SEP1 and the first drain electrode portion DEP 1.

The first channel portion CHN1 is disposed between the first source electrode SE1 and the first drain electrode DE1, particularly between the first doping portion DP1 and the second doping portion DP2.

The gate insulating layer GI is disposed on the first channel portion CHN1 to insulate the first gate electrode GE1 and the first channel portion CHN1 from each other.

The first gate electrode GE1 is disposed on the gate insulating layer GI. The first gate electrode GE1 is branched from the gate line GL. The first gate electrode GE1 and the first source electrode portion SEP1 are spaced apart from each other, and at least a portion of the first doping portion DP1 is disposed between the first gate electrode GE1 and the first source electrode portion SEP1. The first gate electrode GE1 and the first drain electrode portion DEP1 are spaced apart from each other, and at least a portion of the second doping portion DP2 is disposed between the first gate electrode GE1 and the first drain electrode portion DEP1.

The first gate electrode GE1, the gate insulating layer GI under the first gate electrode GE1, and the first channel portion CHN have the same size and the same shape when viewed in a plan view.

The driving thin film transistor DTR includes the second gate electrode GE2, a second channel portion CHN2, the second source electrode SE2, and the second drain electrode DE2.

The second source electrode SE2 includes a second source electrode portion SEP2 branched from the driving voltage line DVL and a third doping portion DP3 that covers at least a portion of the second source electrode portion SEP2 and at least a portion of the upper surface of the base substrate BS. The second drain electrode DE2 includes the second drain electrode portion DEP2 spaced apart from the second source electrode portion SEP2 and a fourth doping portion DP4 that covers at least a portion of the second drain electrode portion DEP2 and at least a portion of the upper surface of the base substrate BS. A portion of each of the third and fourth doping portions DP3 and DP4 is disposed between the second source electrode SEP2 and the second drain electrode portion DEP2. A storage electrode STE is branched from the second gate electrode GE2. The storage electrode STE overlaps the driving voltage line DVL, and the gate insulating layer GI is disposed between the storage electrode STE and the driving voltage line DVL. The storage electrode STE forms the storage capacitor Cst in cooperation with the driving voltage line DVL.

The second channel portion CHN2 is disposed between the second source electrode SE2 and the second drain electrode DE2, particularly between the third doping portion DP3 and the fourth doping portion DP4.

The gate insulating layer GI is disposed on the first channel portion CHN1 to insulate the first gate electrode GE1 and the first channel portion CHN1 and disposed on the second channel portion CHN2 to insulate the second gate electrode GE2 and the second channel portion CHN2 from each other.

The second gate electrode GE2 is disposed on the gate insulating layer GI. The second gate electrode GE2 is connected to the first drain electrode DE1 of the switching thin film transistor STR. The second gate electrode GE2 and the second source electrode portion SEP2 are spaced apart from each other, and at least a portion of the third doping portion DP3 is disposed between the second gate electrode GE2 and the second source electrode portion SEP2. The second gate electrode GE2 and the second drain electrode portion DEP2 are spaced apart from each other, and at least a portion of the fourth doping portion DP4 is disposed between the second gate electrode GE2 and the second drain electrode portion DEP2. The second gate electrode GE2, the gate insulating layer GI under the second gate electrode GE2, and the second channel portion CHN2 have the same size and the same shape when viewed in a plan view.

The diffusion layer DFL and the passivation layer PSV are disposed on the switching thin film transistor STR and the driving thin film transistor DTR. The diffusion layer DFL includes impurities and diffuses the impurities into the first doping portion DP1 and the second doping portion DP2. According to an embodiment, the diffusion layer DFL is omitted. The passivation layer PSV is penetrated by a first contact hole CH1 to expose a portion of the first drain electrode DE1, a second contact hole CH2 to expose a portion of the second gate electrode GE2, and a third contact hole CH3 to expose a portion of the second drain electrode DE2.

A bridge electrode BRE connects the first drain electrode DE1 with the second gate electrode GE2. The bridge electrode BRE and the first electrode EU are disposed on the passivation layer PSV. The bridge electrode BRE contacts the first drain electrode DE1 through the first contact hole CH1 and contacts the second gate electrode GE2 through the second contact hole and CH2 so that the first drain electrode DE1 is electrically connected to the second gate electrode GE2. The first electrode EL1 is connected to the second drain electrode DE2 through the third contact hole CH3.

A barrier wall WL is disposed on the base substrate BS on which the first electrode EL1 is provided. The barrier wall WL is provided along the circumference of the first electrode EL1 to define a space in which the organic light emitting layer LDL is accommodated. The space corresponds to a pixel.

The organic light emitting layer LDL is disposed on the first electrode ELI in the space defined by the barrier wall WL. The organic light emitting layer LDL includes an organic light emitting material that represents red, green, blue, or white color. In FIG. 11B, the organic light emitting layer LDL has a single-layer structure, but it should not be limited thereto or thereby. According to an embodiment, the organic light emitting layer LDL has a multi-layer structure. For instance, according to an embodiment, an electron injection layer, an electron transfer layer, a hole injection layer, and a hole transfer layer are further employed in the organic light emitting layer LDL.

The second electrode EL2 is disposed on the organic light emitting layer LDL. According to an embodiment, the second electrode EL2 is disposed over the whole or part of a top surface of the base substrate BS.

According to an embodiment, an encapsulating layer is provided on the second electrode to encapsulate and protect the formed elements, such as, for example, the organic light emitting layer LDL, the transistor DTR, or the transistor STR.

The display apparatus displays an image toward an upper or lower direction of the base substrate BS. In the display apparatus, the direction in which the image is displayed is changed depending on the material and the transparency of the first and second electrodes EL1 and EL2. For example, according to an embodiment, when the first electrode EL1 is non-transparent, and the second electrode EL2 is transparent, the display apparatus displays an image toward the upper direction of the base substrate BS. Alternatively, when the first electrode EL1 is transparent, and the second electrode EL2 is non-transparent, the display apparatus displays an image toward the lower direction of the base substrate BS.

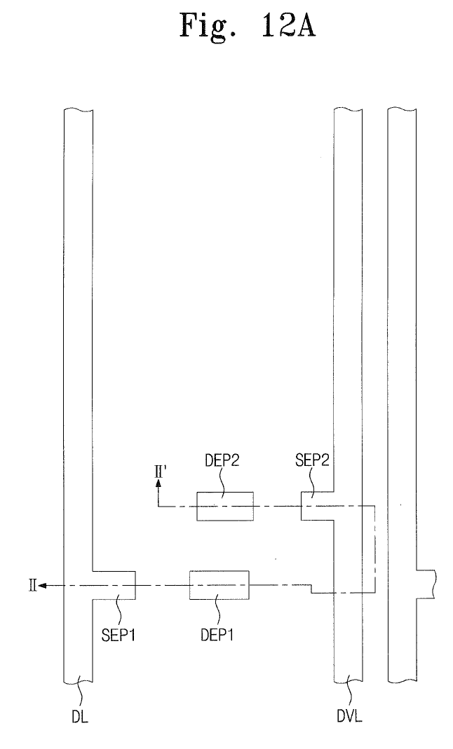

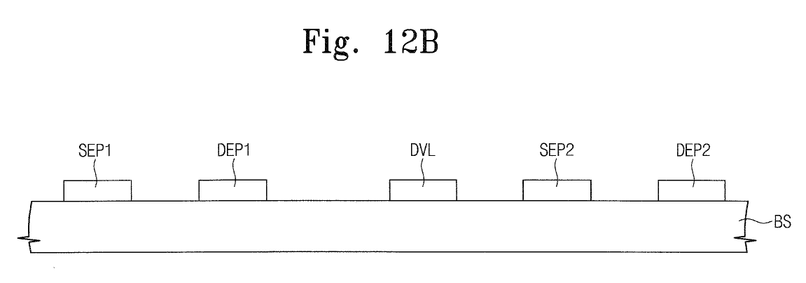

FIGS. 12A, 13A, 14A, 15A, 16A, and 17A are plan views showing a method of manufacturing a display apparatus according to the exemplary embodiment of the present invention shown in FIGS. 11A and 11B, and FIGS. 12B, 13B, 14B, 15B, 16B, and 17B are cross-sectional views taken along a line II-II′ shown in FIGS. 12A, 13A, 14A, 15A, 16A, and 17A, respectively.

Referring to FIGS. 12A and 12B, the data line part is formed on the base substrate BS. The data line part includes the data line DL, the first source electrode portion SEP1, the first drain electrode portion DEP1, the second source electrode SEP2, the second drain electrode portion DEP2, and the driving voltage line DVL.

The data line part is formed of a conductive material, such as a metal. For instance, according to an embodiment, the data line part is formed by forming a metal layer over a top surface of the base substrate BS and patterning the metal layer using a photolithography process. The data line part has a single-layer structure of a single metal layer or an alloy of two or more metals, but it should not be limited thereto or thereby. According to an embodiment, the data line part has a multi-layer structure of two or more metals and/or alloys thereof. The data line DL and the first source electrode portion SEP1 are integrally formed with each other as a single body, and the driving voltage line DVL and the second source electrode portion SEP2 are integrally formed with each other as a single body.

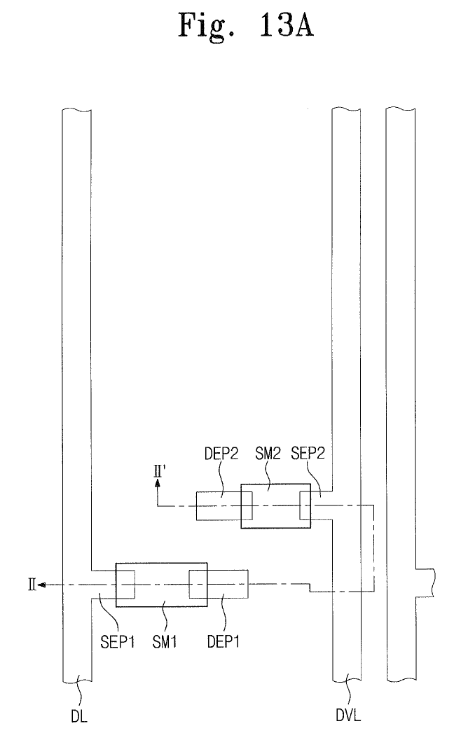

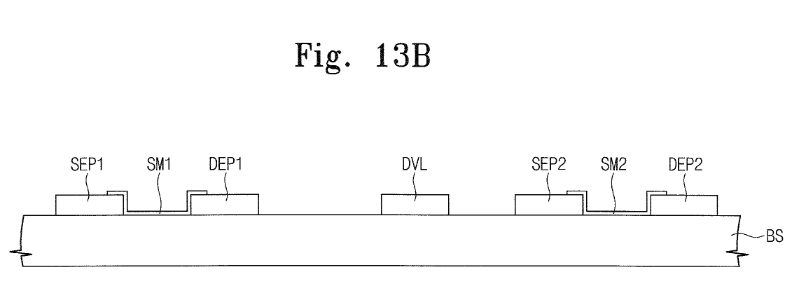

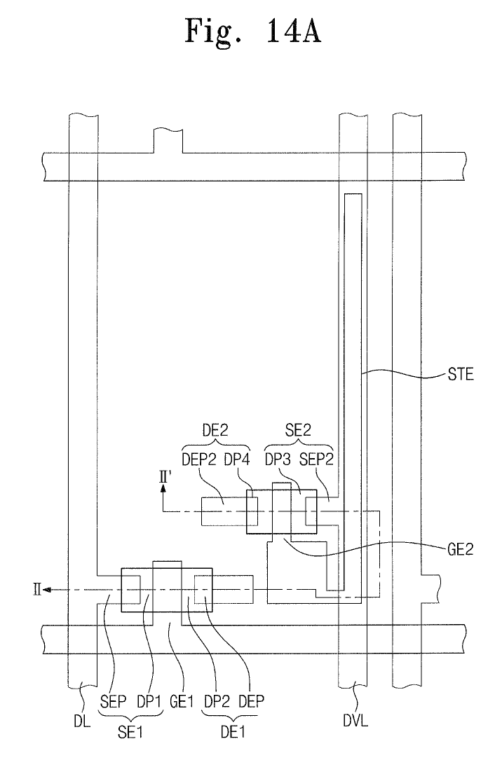

Referring to FIGS. 13A and 13B, a first oxide semiconductor layer SM1 is formed between the first source electrode portion SEP1 and the first drain electrode portion DEP1, and a second oxide semiconductor layer SM2 is formed between the second source electrode portion SEP2 and the second drain electrode portion DEP2. The first oxide semiconductor layer SM1 overlaps and covers at least a portion of each of the first source electrode portion SEP1 and the first drain electrode portion DEP1. The second oxide semiconductor layer SM2 overlaps and covers at least a portion of each of the second source electrode portion SEP2 and the second drain electrode portion DEP2.

The first oxide semiconductor layer SM1 and the second oxide semiconductor layer SM2 are formed of an oxide material that includes at least one of indium (In), gallium (Ga), zinc (Zn), or tin (Sn). The first and second oxide semiconductor layers SM1 and SM2 are formed by forming the oxide material to cover at least a portion between the first source electrode portion SEP1 and the first drain electrode portion DEP1 and to cover at least a portion between the second source electrode portion SEP2 and the second drain electrode portion DEP2 and by patterning the oxide material using a photolithography process.

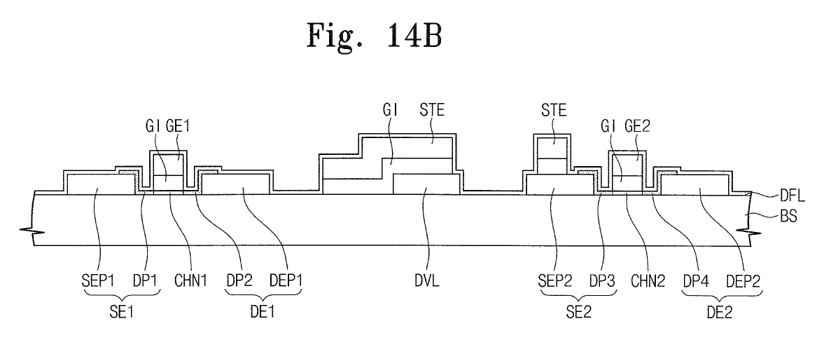

Referring to FIGS. 14A and 14B, the gate insulating layer GI and the gate line part are formed on the base substrate BS. The gate line part includes the gate line GL, the first gate electrode GE1, the second gate electrode GE2, and the storage electrode STE. The gate insulating layer GI and the gate line part are formed by sequentially forming an insulating material, such as silicon nitride or silicon oxide, and a conductive material, such as metal, on the base substrate BS and by patterning the insulating material and the conductive material using a photolithography process. The first gate electrode GE1 is disposed between the first source electrode portion SEP1 and the first drain electrode portion DEP1 and spaced apart from the first source electrode portion SEP1 and the first drain electrode portion DEP1. The second gate electrode GE2 is disposed between the second source electrode portion SEP2 and the second drain electrode portion DEP2 and spaced apart from the second source electrode portion SEP2 and the second drain electrode portion DEP2. The storage electrode STE is patterned to overlap the driving voltage line DVL. The gate line GL and the first gate electrode GE1 are integrally formed with each other as a single body, and the second gate electrode GE2 and the storage electrode STE are integrally formed with each other as a single body.

Then, the first doping portion DP1, the second doping portion DP2, the third doping portion DP3, and the fourth doping portion DP4, which are doped with a high concentration of impurities, and the first and second channel portions CHN1 and CHN2, which are not doped with the impurities, are formed on the base substrate BS.

The first doping portion DP1, the second doping portion DP2, the third doping portion DP3, the fourth doping portion DP4, the first channel portion CHN1, and the second channel portion CHN2 are formed by forming a diffusion layer DFL on the base substrate BS and by annealing the diffusion layer DFL so that the impurities in the diffusion layer DFL are diffused into the first oxide semiconductor layer SM1 and the second oxide semiconductor layer SM2. Alternatively, the first doping portion DP1, the second doping portion DP2, the third doping portion DP3, the fourth doping portion DP4, the first channel portion CHN1, and the second channel portion CHN2 may be formed by using a plasma process. According to an embodiment, when the first doping portion DP1, the second doping portion DP2, the third doping portion DP3, the fourth doping portion DP4, the first channel portion CHN1, and the second channel portion CHN2 are formed by the plasma process, the diffusion layer DFL may be omitted. According to an embodiment, the plasma process is performed by plasma-treating the base substrate BS, on which the first doping portion DP1, the second doping portion DP2, the third doping portion DP3, the fourth doping portion DP4, the first channel portion CHN1, and the second channel portion CHN2 are formed, using impurities including, e.g., H₂ or NH₃.

The portions of the first and second oxide semiconductor layers SM1 and SM2, which are not covered by the first and second gate electrodes GE1 and GE2 and the gate insulating layer GI, are doped with, e.g., hydrogen through the plasma-treating process, and thus the first doping portion DP1, the second doping portion DP2, the third doping portion DP3, and the fourth doping portion DP4 are formed. The portions of the first and second oxide semiconductor layers SM1 and SM2, which are covered with the gate insulating layer GI and the first and second gate electrodes GE1 and GE2, are not plasma-treated, remain undoped with the impurities. For example, the first and second gate electrodes GE1 and GE2 (and the gate insulting layer GI) are used as masks when the first and second oxide semiconductor layers SM are doped with the impurities, and the portions of the first and second oxide semiconductor layers SM1 and SM2, which are covered by the masks, are formed as the first and second channel portions CHN1 and CHN2.

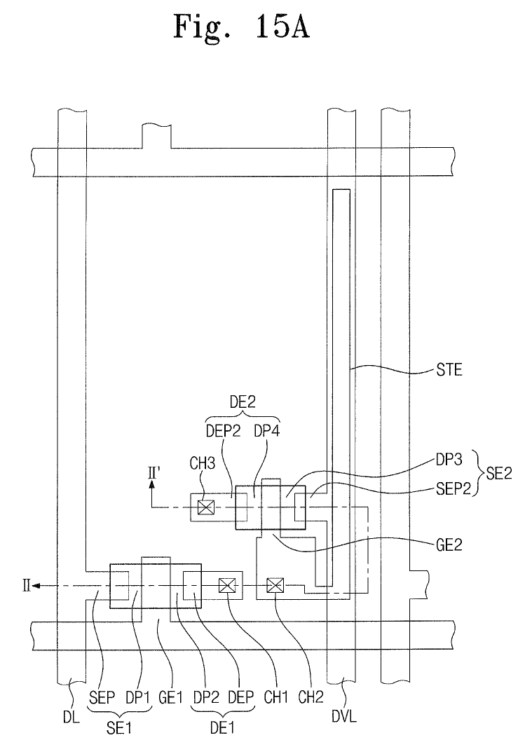

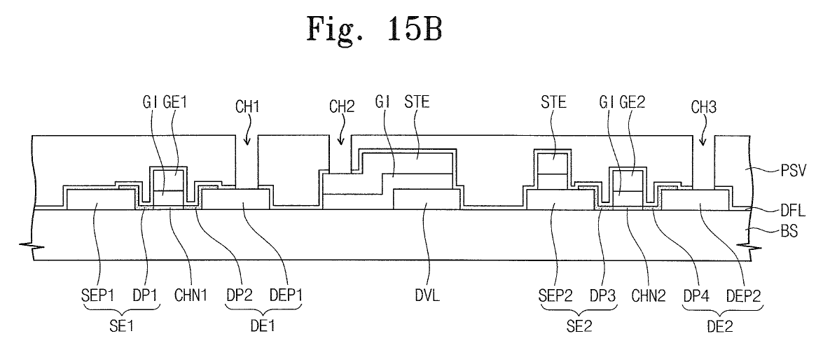

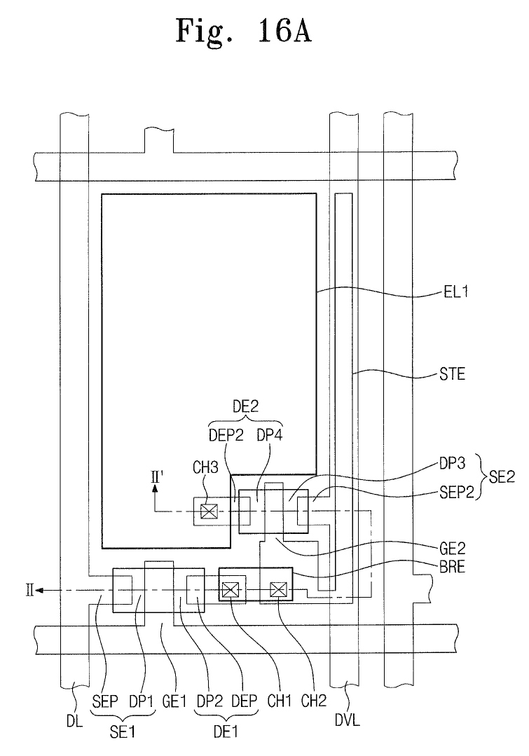

Referring to FIGS. 15A and 15B, the passivation layer PSV is formed on the base substrate BS. The passivation layer PSV includes the first contact hole CH1 to expose the portion of the first drain electrode DEI, the second contact hole CH2 to expose the portion of the second gate electrode GE2, and the third contact hole CH3 to expose the portion of the second drain electrode DE2. According to an embodiment, the first, second, and third contact holes CH1, CH2, and CH3 are formed using a photolithography process.

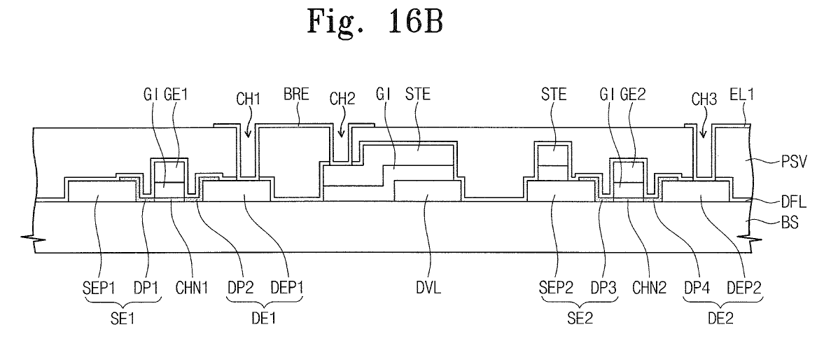

Referring to FIGS. 16A and 16B, the bridge electrode BRE and the first electrode EL1 are formed on the base substrate BS on which the passivation layer PSV is formed. The bridge electrode BRE and the first electrode EL1 are formed by forming a conductive layer using a conductive material and by patterning the conductive layer using a photolithography process. The bridge electrode BRE is connected to the first drain electrode DE1 and the second gate electrode GE2 through the first contact hole CH1 and the second contact hole CH2. The first electrode EL1 is connected to the second drain electrode DE2 through the third contact hole CH3.

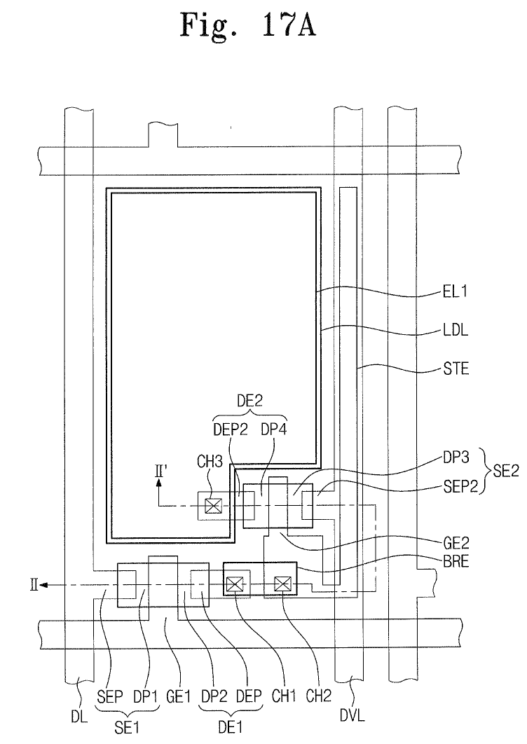

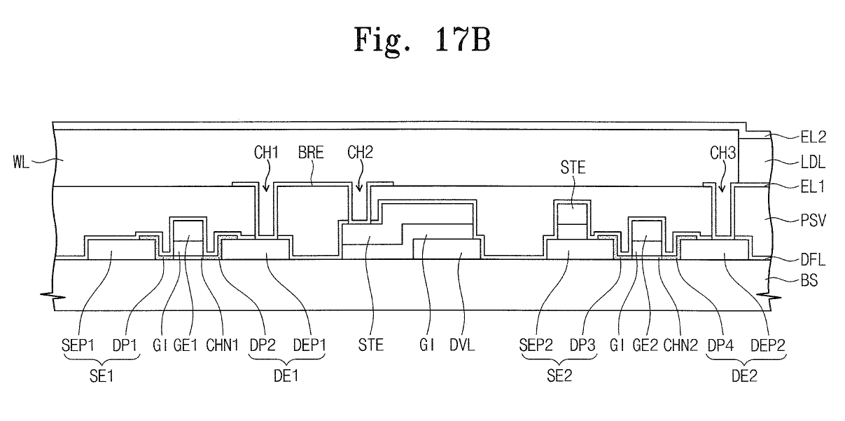

Referring to FIGS. 17A and 17B, the barrier wall WL is formed on the base substrate BS. The barrier wall WL is formed by depositing an organic material or an inorganic material and by patterning the organic material or the inorganic material. The barrier wall WL is patterned to expose an upper surface of the first electrode EL1. The barrier wall WL includes a space.

The organic light emitting layer LDL is formed in the space as an image display layer. According to an embodiment, the organic light emitting layer LDL is formed by a solution process, such as an inkjet printing method, or an evaporation process.

The second electrode EL2 is formed on the organic light emitting layer LDL. The second electrode EL2 is formed over a top surface of the base substrate BS.

According to an embodiment, an opposite base substrate is provided on the second electrode EL2, or a protective layer is provided on the second electrode EL2 to cover the second electrode EL2.

The display apparatuses according to the exemplary embodiments can provide stable, low-voltage displaing operation and reduced manufacturing cost. Further, since the thin film transistor is uniformly formed on a large area at a relatively low temperature, the electronic device can be formed on a flexible substrate, such as a plastic substrate, which is processed at a relatively low temperature.

As the electronic device in which the thin film transistor according to the exemplary embodiments is employed, the display apparatus has been described, but the electronic device should not be limited to the display apparatus. The liquid crystal display device and the organic light emitting display device have been described as the display apparatus, but the display apparatus should not be limited to the liquid crystal display device and the organic light emitting display device. According to embodiments, various display apparatuses, such as an electrophoresis display apparatus, or an electrowetting display apparatus may be used as the display apparatus. The electrophoresis display apparatus, which utilizes an electrophoretic phenomenon, includes an electrophoretic layer corresponding to the image display layer. The electrowetting display apparatus, which utilizes a wetting phenomenon, includes an electrowetting layer corresponding to the image display layer.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A thin film transistor comprising:
a source electrode;
a drain electrode;
a channel portion between the source electrode and the drain electrode; and
a gate electrode on the channel portion, the gate electrode insulated from the channel portion, wherein the source electrode, the drain electrode, and the channel portion are disposed on a same layer.

2. The thin film transistor of claim 1, wherein the source electrode comprises a source electrode portion and a first doping portion that covers at least a portion of the source electrode portion, and the drain electrode comprises a drain electrode portion and a second doping portion that covers at least a portion of the drain electrode portion, and wherein the first doping portion and the second doping portion each comprise a doped oxide semiconductor.

3. The thin film transistor of claim 2, wherein the channel portion is disposed between the first doping portion and the second doping portion and comprises an oxide semiconductor.

4. The thin film transistor of claim 3, wherein the oxide semiconductor comprises at least one of indium, gallium, zinc, or tin.

5. The thin film transistor of claim 3, wherein the oxide semiconductor of the channel portion has a doping concentration lower than a doping concentration of the doped oxide semiconductor of the first doping portion and the second doping portion.

6. The thin film transistor of claim 2, further comprising a gate insulating layer between the channel portion and the gate electrode, wherein the gate electrode, the gate insulating layer, and the channel portion overlap each other and have a same size and shape when viewed in a plan view.

7. The thin film transistor of claim 2, wherein the gate electrode is spaced apart from the source electrode portion and the drain electrode portion.

8. The thin film transistor of claim 7, wherein the gate electrode and the source electrode portion are spaced apart from each other, and at least a portion of the first doping portion is disposed between the gate electrode and the source electrode portion.

9. The thin film transistor of claim 7, wherein the gate electrode and the drain electrode portion are spaced apart from each other, and at least a portion of the second doping portion is disposed between the gate electrode and the drain electrode portion.

10. The thin film transistor of claim 7, wherein the source electrode portion comprises an upper surface and a side surface, and the first doping portion directly contacts at least a portion of each of the upper surface and the side surface of the source electrode portion.

11. The thin film transistor of claim 7, wherein the drain electrode portion comprises an upper surface and a side surface, and the second doping portion directly contacts at least a portion of each of the upper surface and the side surface of the drain electrode portion.

12. The thin film transistor of claim 2, wherein at least one of the source electrode portion or the drain electrode portion comprises at least one of a metal, a metal alloy, or a metal oxide.

13. A display apparatus comprising:
a display device; and
a thin film transistor configured to apply a driving signal to the display device, the thin film transistor comprising:
a source electrode;
a drain electrode;
a channel portion between the source electrode and the drain electrode; and
a gate electrode on the channel portion, the gate electrode insulated from the channel portion, wherein the source electrode, the drain electrode, and the channel portion are disposed on a same layer.

14. A method of manufacturing a thin film transistor, the method comprising:
forming a source electrode portion and a drain electrode portion on a base substrate;
forming an oxide semiconductor layer between the source electrode portion and the drain electrode portion;
forming a gate electrode on the oxide semiconductor layer; and
doping the oxide semiconductor layer with an impurity using the gate electrode as a mask to form a first doping portion and a second doping portion, which are doped with the impurity, and a channel portion disposed between the first doping portion and the second doping portion.

15. The method of claim 14, further comprising:
forming a thin layer containing the impurity; and
annealing the base substrate on which the thin layer is formed.

16. The method of claim 15, wherein the impurity is aluminum.

17. The method of claim 14, further comprising plasma-treating the base substrate using H₂ or NH₃.

18. The method of claim 14, wherein the channel portion is spaced apart from each of the source electrode portion and the drain electrode portion.

19. The method of claim 14, wherein at least one of the source electrode portion or the drain electrode portion has a single-layer structure or a multi-layer structure.

20. The method of claim 14, further comprising:
forming a first electrode connected to the drain electrode;
forming a second electrode facing the first electrode; and
forming an image display layer between the first electrode and the second electrode.

21. A thin film transistor comprising:
a source electrode portion and a drain electrode portion on a base substrate;
an oxide semiconductor layer between the source and drain electrode portions on the base substrate, wherein the oxide semiconductor layer includes a channel and first and second doped portions respectively contacting the source and drain electrodes; and
a gate electrode on the channel, wherein the gate electrode does not overlap the source electrode portion nor the drain electrode portion in a direction substantially perpendicular to a top surface of the base substrate.
